(19) United States
(12) Patent Application Publication
(10) Pub. No.: US 2023/0192514 A1
(43) Pub. Date: Jun. 22, 2023

(54) HIGH-SPECIFIC SURFACE AREA AND SUPER-HYDROPHILIC GRADIENT BORON-DOPED DIAMOND ELECTRODE, METHOD FOR PREPARING SAME AND APPLICATION THEREOF

(71) Applicant: NANJING DAIMONTE TECHNOLOGY CO., LTD., Nanjing (CN)

(72) Inventors: Qiuping WEI, Changsha (CN); Li MA, Changsha (CN); Kechao ZHOU, Changsha (CN); Lifeng WANG, Changsha (CN); Baofeng WANG, Changsha (CN); Haiping SHI, Changsha (CN)

(73) Assignee: NANJING DAIMONTE TECHNOLOGY CO., LTD., Nanjing (CN)

(21) Appl. No.: 17/924,690

(22) PCT Filed: May 10, 2021
(86) PCT No.: PCT/CN2021/092781

§ 371 Date: Nov. 11, 2022

(30) Foreign Application Priority Data
May 11, 2020 (CN) 202010390579.2

(51) Int. Cl. C02F 1/461; C23C 16/02; C23C 16/27; C23C 16/56; C02F 1/467

(52) U.S. Cl. CPC C02F 1/46109; C23C 16/0272; C23C 16/0227; C23C 16/278; C23C 16/277; C23C 16/56; C02F 1/4672; C23C 16/271; C02F 2101/30

(57) ABSTRACT

A high-specific surface area and super-hydrophilic gradient boron-doped diamond electrode is disclosed. The electrode directly uses a substrate as an electrode matrix; or a transition layer is disposed on a surface of the substrate and used as the electrode matrix. A gradient boron-doped diamond layer is disposed on a surface of the electrode matrix, and a contact angle of the electrode is θ<40°. The gradient boron-doped diamond layer includes: a gradient boron-doped diamond bottom layer, a gradient boron-doped diamond middle layer, and a gradient boron-doped diamond top layer, a boron content of which gradually increases, so the gradient boron-doped diamond layer has high adhesion, high corrosion resistance, and high catalytic activity. The high-content boron of the top layer is combined with a one-time high-temperature treatment, so the gradient boron-doped diamond electrode has a high-specific surface area and superhydrophilicity, which may greatly improve the mineralization and degradation efficiency of the electrode.

### CROSS REFERENCE TO THE RELATED APPLICATIONS

This application is the national phase entry of International Application No. PCT/CN2021/092781, filed on May 10, 2021, which is based upon and claims priority to Chinese Patent Application No. 202010390579.2, filed on May 11, 2020, the entire contents of which are incorporated herein by reference.

### TECHNICAL FIELD

The disclosure relates to a high-specific surface area and super-hydrophilic gradient boron-doped diamond electrode, a method for preparing same and an application thereof, belonging to the field of electrode preparation.

### BACKGROUND

With the advantages of wide potential window, good chemical stability and weak surface adsorption, boron-doped diamond (BDD) materials have a higher mineralization effect on organic pollutants in a water body than other electrochemical oxidation electrodes (such as PbO₂, dimensionally stable anodes (DSA), IrO₂, etc.). The degradation efficiency of the existing traditional plate BDD electrode material is controlled by the diffusion rate in the system and affected by sp³/sp² (ratio of sp³ carbon to sp² carbon) inside the material. Therefore, there are four ways to improve the mineralization efficiency of a BDD electrode material for organic matters: (1) increasing the specific surface area of the electrode material, so as to increase the yield of active substances (such as hydroxyl radical ·OH) per unit macroscopic area; (2) improving the fluid distribution state on the electrode surface, so as to increase the mass exchange between the surface organic matters and the active substances and further increase the probability of reaction between the organic matters and the active substances; (3) increase the surface sp³/sp² of the electrode material, which may further improve the weak surface adsorption of the material so as to improve the utilization efficiency of various active substances produced; and (4) improving the hydrophilicity of the electrode material.

BDD etching is one of the methods that can improve the mineralization efficiency of the BDD electrode material for organic matters. According to the BDD etching methods in the prior art, a BDD coating is deposited onto the surface of a plate matrix by vapor deposition (CVD), and then, micropores, diamond nanowires or diamond nanoarrays are etched on the surface of the BDD by plasma etching, high-temperature catalytic metal ion etching or two-step high-temperature etching. However, such methods are complex in process and have high requirements for equipment, and the masking material may be introduced in the etching process, causing contamination to the BDD material. Especially in the high-temperature catalytic metal ion etching, harmful heavy metal ions such as nickel ions may be introduced into the water body in the late period, resulting in water body pollution.

### SUMMARY

In view of the defects in the prior art, a first object of the disclosure is to provide a high-specific surface area and super-hydrophilic gradient boron-doped diamond electrode.

A second object of the disclosure is to provide a method for preparing a high-specific surface area and super-hydrophilic gradient boron-doped diamond electrode.

A third object of the disclosure is to provide an application of a high-specific surface area and super-hydrophilic gradient boron-doped diamond electrode.

To achieve the foregoing objective, the disclosure adopts the following technical solutions:

According to the high-specific surface area and super-hydrophilic gradient boron-doped diamond electrode of the disclosure, the gradient boron-doped diamond electrode directly uses a substrate as an electrode matrix; or a transition layer is disposed on a surface of the substrate and then used as the electrode matrix, and a gradient boron-doped diamond layer is then disposed on a surface of the electrode matrix. A contact angle of the gradient boron-doped diamond electrode is θ<40°.

According to the high-specific surface area and super-hydrophilic gradient boron-doped diamond electrode of the disclosure, the gradient boron-doped diamond layer includes, in succession from bottom to top, a gradient boron-doped diamond bottom layer, a gradient boron-doped diamond middle layer, and a gradient boron-doped diamond top layer, a boron content of which gradually increases.

According to the high-specific surface area and super-hydrophilic gradient boron-doped diamond electrode of the disclosure, in the gradient boron-doped diamond bottom layer, an atomic ratio B/C is 3333-33333 ppm, preferably 3333-10000 ppm. In the gradient boron-doped diamond middle layer, an atomic ratio B/C is 10000-33333 ppm, preferably 13332-20000 ppm. In the gradient boron-doped diamond top layer, an atomic ratio B/C is 16666-50000 ppm, preferably 26664-50000 ppm.

Due to the difference of radius between the boron atom and the carbon atom and the difference of length between the B—C bond and the C—C bond, the doping of boron will lead to improved conductivity and electrochemical activity of the material, i.e., lower energy consumption and improved performance during service. However, on the one hand, boron will lead to distortion of the diamond lattice, increasing the defects in the material, and thus reducing the stability of diamond lattice. On the other hand, the increase in boron concentration will lead to an increase in the content of the sp² carbon in the material, which will also reduce the stability of the thin film.

In the disclosure, the doping content of boron gradually increases from the bottom to the top of the thin film. The doping content of boron in the bottom layer with high adhesion is extremely low so as to ensure the bonding and stability of the thin film. The bottom layer is in direct contact with the electrode matrix. In the early stage of deposition, the diamond phase is easy to nucleate, with fewer defects and less sp² carbon. This can further increase the sp³ content and lattice stability of the nucleation surface, thereby increasing the adhesion to the electrode matrix. The middle layer, which is corrosion-resistant, has a medium boron content (i.e. higher than the bottom layer and lower than the top layer). The boron content in the middle layer is still very low, which can thus ensure the purity of the sp³ phase (i.e., the diamond is dense and continuous). In addition, the certain doping content of boron can also ensure the conductivity of this layer. The high doping content of boron in the top layer can improve the conductivity and electrochemical activity of the material, so that the top layer has wide potential window, high oxygen evolution potential and low background current. The diamond top layer can greatly improve the electrocatalytic activity and degradation efficiency of the electrode. Meanwhile, the hydrophilicity will also increase with the increase of the boron content.

Of course, for the disclosure, the way of gradient boron doping and the boron content in each layer are crucial to the performance of the gradient boron-doped diamond electrode of the disclosure. For example, if the same boron content is used instead of gradient boron doping, there will be two problems: First, if the three layers have the same boron content as in the bottom layer, the boron content will be too low, which makes the diamond lattice inside the thin film stable. However, the too low doping content of boron will lead to a lower conductivity of the whole thin film, which will greatly increase the energy consumption of the material during service. The high-temperature treatment is used to etch the material, and thus, will damage the material. The low boron content in all the three layers will lead to the absence of the high-catalytic-activity layer having high doping content of boron, causing low performance of the electrode; and it is also impossible to obtain the superhydrophilicity of the electrode in the disclosure.

Second, if the boron content is too high (the three layers have the same boron content as in the top layer), the conductivity of the material will be increased. However, due to the high doping content of boron, there will be severe distortion of the diamond lattice, and a large amount of sp² carbon will be introduced into the material. This will destroy the weak adsorption of the diamond, reduce the potential window of the electrode material and lower the corrosion resistance of the material. If all the three layers have a high doping content of boron, there will be no bottom layer with high adhesion to provide stability after the electrode material is damaged in the late period, which makes the thin film easily become separated (fall off) from the substrate, causing a serious reduction in service life of the material.

In a case of an unreasonably designed boron content, if the doping content of boron in the middle layer is too low, the diamond lattice inside the thin film will be stable. However, the too low doping content of boron will lead to a lower conductivity of the whole thin film, which will greatly increase the energy consumption of the material during service. If the doping content of boron in the middle layer is too high, the conductivity of the material will be increased. However, due to the high doping content of boron, there will be severe distortion of the diamond lattice, and a large amount of sp² carbon will be introduced into the material. This will destroy the weak adsorption of the diamond, reduce the potential window of the electrode material and lower the corrosion resistance of the material.

According to the high-specific surface area and super-hydrophilic gradient boron-doped diamond electrode of the disclosure, the gradient boron-doped diamond layer is uniformly deposited on the surface of the substrate by chemical vapor deposition. The gradient boron-doped diamond layer has a thickness of 5 μm-2 mm.

According to the high-specific surface area and super-hydrophilic gradient boron-doped diamond electrode of the disclosure, a thickness of the gradient boron-doped diamond middle layer accounts for 50%-90% of the thickness of the gradient boron-doped diamond layer. A thickness of the gradient boron-doped diamond top layer accounts for less than 40% of the thickness of the gradient boron-doped diamond layer.

The gradient boron-doped diamond bottom layer, the gradient boron-doped diamond middle layer and the gradient boron-doped diamond top layer of the disclosure have different functions. The bottom layer functions to improve the bonding between the substrate and the thin film. The top layer functions to provide high electrochemical activity (high catalytic activity) and high hydrophilicity. The middle layer, serving as the main body of the thin film material, functions to conduct electricity and resist corrosion during service. Therefore, the thickness of the middle layer needs to account for more than half of the thickness of the gradient boron-doped diamond layer. The reason for controlling the thickness of the top layer to account for less than 40% of the thickness of the gradient boron-doped diamond layer is that the increase in the boron content will lead to an increase in the sp² carbon (graphitic carbon). According to the disclosure, the percentage of the thickness of the top layer is controlled within 10%. This can avoid the excessive introduction of sp² carbon, which can improve the hydrophilicity and also ensure the hydrophilicity and high catalytic activity of the material.

According to the high-specific surface area and super-hydrophilic gradient boron-doped diamond electrode of the disclosure, micropores and/or spikes are distributed on a surface of the gradient boron-doped diamond layer. The micropores have a diameter of 500 nm-0.5 mm, and the spikes have a diameter of 1 μm-30 μm.

In the disclosure, there is no limit to the selection of the substrate material, and all the substrate materials reported in the prior art are suitable as the substrate of the disclosure. However, for some substrate materials, a transition layer is needed before the gradient boron-doped diamond layer is disposed. There are two cases that need the disposition of the transition layer. The first case is that the thermal expansion coefficient of the substrate material is too high. Such substrate materials are usually metal materials (such as nickel (Ni), tantalum (Ta), niobium (Nb), etc.). Due to the low expansion coefficient of the diamond (CTE=1.8CTE_{Ni}=13.0×10⁻⁶° C.⁻¹), the too high expansion coefficient of the substrate material will lead to excessive internal stress caused by the temperature change (the temperature changes from 800-900° C. to room temperature) during thin film deposition, resulting in thermal mismatch during the preparation and/or service. This, in a mild case, leads to impaired material performance and service life, and in a severe case, makes the thin film become separated (fall off) from the substrate. The introduction of the transition layer with a proper thermal expansion coefficient can effectively reduce the thermal stress at the interface between the thin film and the substrate, thereby improving the service performance and the service life of the material.

The other case is that the substrate material is not suitable for diamond nucleation. Such substrate materials are usually non-carbide-forming element materials. The chemical vapor deposition (CVD) used in the disclosure requires carbon-containing active groups to nucleate and grow on the surface of the substrate material in the deposition process. However, non-carbide-forming elements are incapable of forming a carbide transition layer in the deposition process, which makes it difficult for diamond to nucleate, thus lowering the quality of the thin film. The introduction of the transition layer can effectively improve the efficiency of chemical vapor deposition, the continuity of the thin film and the bonding between the thin film and the substrate.

According to the high-specific surface area and super-hydrophilic gradient boron-doped diamond electrode of the disclosure, a substrate material is selected from one of metals nickel, niobium, tantalum, copper, titanium, cobalt, tungsten, molybdenum, chromium and iron or one of alloys thereof; or an electrode substrate material is selected from one of ceramics Al₂O₃, ZrO₂, SiC, Si₃N₄, BN, B₄C, AlN, TiB₂, TiN, WC, Cr₇C₃, Ti₂GeC, Ti₂AlC and Ti₂AlN, Ti₃SiC₂, Ti₃GeC₂, Ti₃AlC₂, Ti₄AlC₃ and BaPO₃, or a doped ceramic thereof; or the electrode substrate material is selected from one of composite materials composed of the metal and the ceramic above, or the substrate material is selected from diamond or Si.

According to the high-specific surface area and super-hydrophilic gradient boron-doped diamond electrode of the disclosure, the substrate is in a shape of a solid cylinder, a hollow cylinder or a plate. The substrate is in a three-dimensional continuous network structure, a two-dimensional continuous network structure or a two-dimensional closed plate structure.

Preferably, the substrate material is selected from one of titanium, nickel and silicon.

According to the high-specific surface area and super-hydrophilic gradient boron-doped diamond electrode of the disclosure, a transition layer material is selected from at least one of titanium, tungsten, molybdenum, chromium, tantalum, platinum, silver, aluminum, copper and silicon, and the transition layer has a thickness of 50 nm-10 μm.

In the disclosure, as long as the transition layer has a satisfactory thickness and good bonding, the method for preparing the transition layer is not limited, and for example, may be one of electroplating, electroless plating, evaporation, magnetron sputtering, chemical vapor deposition and physical vapor deposition in the prior art.

Preferably, when the substrate material is nickel, the transition layer material is titanium. Nickel (Ni), as a common electrocatalytic material that can be easily electrodeposited, can be processed into complex structures and shapes, so nickel is suitable as a substrate material. However, Ni can easily catalyze the reaction of diamond to form other amorphous carbon, so it is impossible to directly deposit a boron-doped diamond film. Due to the big difference in thermal expansion coefficient between Ni and C, it impossible to form an effective carbide transition layer, and foam has poor bonding with the substrate. During the degradation experiment, Ni is easily sacrificed, resulting in a reduced service life of the BDD electrode. Therefore, in the disclosure, a Ti film that can completely cover the matrix is first sputtered on the foam Ni matrix. Ti not only can easily form a TiC layer with C, thus solving the problem of thermal mismatch, but also has good bonding with Ni.

According to the high-specific surface area and super-hydrophilic gradient boron-doped diamond electrode of the disclosure, the gradient boron-doped diamond electrode is in a structure of a cylindrical type, a planar spiral type, a cylindrical spiral type, a planar woven network type, a three-dimensional woven network type, a honeycomb-like porous type or a foam-like porous type.

The method for preparing a high-specific surface area and super-hydrophilic gradient boron-doped diamond electrode of the disclosure includes the following steps.

Step I: Pretreatment of Electrode Matrix.

An electrode matrix is put into a suspension containing nanocrystalline and/or microcrystalline diamond mixed particles; ultrasonic treatment and drying are carried out; and an electrode matrix with nanocrystalline and/or microcrystalline diamond adsorbed to the surface is obtained.

Step II: Deposition of Gradient Boron-Doped Diamond Layer.

The electrode matrix obtained in step I is put into a chemical vapor deposition reactor, and three-stage deposition is carried out on the surface of the electrode matrix to obtain a gradient boron-doped diamond layer. In the first-stage deposition process, a carbon-containing gas accounts for 1%-5% of a mass flow rate of all gasses in the reactor, and a boron-containing gas accounts for 0.005%-0.05% of the mass flow rate of all the gasses in the reactor. In the second-stage deposition process, the carbon-containing gas accounts for 1%-5% of the mass flow rate of all the gasses in the reactor, and the boron-containing gas accounts for 0.015%-0.05% of the mass flow rate of all the gasses in the reactor. In the third-stage deposition process, the carbon-containing gas accounts for 1%-5% of the mass flow rate of all the gasses in the reactor, and the boron-containing gas accounts for 0.025%-0.075% of the mass flow rate of all the gasses in the reactor.

Step III: High-Temperature Treatment.

Heat treatment is carried out on the electrode matrix with the deposited gradient boron-doped diamond layer at a temperature of 400-1200° C. for 5-110 min. The heat treatment is carried out under a pressure of 10 Pa-10⁵ Pa in an etching atmosphere.

In the actual operation, when the substrate is used as the electrode matrix, the substrate is first subjected to ultrasonic treatment in acetone for 5-20 min such that oil stains on the surface of the substrate material are removed, and then the substrate material is rinsed with deionized water and/or anhydrous ethanol, and dried for later use. When the transition layer is disposed on the surface of the substrate and then used as the electrode matrix, the above process is carried out before the transition layer is disposed on the surface of the substrate.

According to the method for preparing a high-specific surface area and super-hydrophilic gradient boron-doped diamond electrode of the disclosure, in step I, in the suspension containing nanocrystalline and/or microcrystalline diamond mixed particles, a mass fraction of the diamond mixed particles is 0.01/6-0.05%.

According to the method for preparing a high-specific surface area and super-hydrophilic gradient boron-doped diamond electrode of the disclosure, in step I, the diamond mixed particles have a particle size of 5-30 nm and a purity of greater than or equal to 97%.

According to the method for preparing a high-specific surface area and super-hydrophilic gradient boron-doped diamond electrode of the disclosure, in step I, the ultrasonic treatment is carried out for 5-30 min. After the completion of the ultrasonic treatment, the electrode matrix is taken out, rinsed with deionized water and/or anhydrous ethanol and then dried.

According to the method for preparing a high-specific surface area and super-hydrophilic gradient boron-doped diamond electrode of the disclosure, in step II, the gasses in the reactor include a boron-containing gas, a carbon-containing gas and hydrogen.

In the disclosure, the hydrogen can be used as both a dilution gas in the chemical deposition process and as an etching gas. In the actual operation, after the three-stage deposition is completed, the boron-containing gas and the carbon-containing gas are stopped first, and the hydrogen continues to be introduced for a period of time to etch the graphite phase on the surface of the gradient boron-doped diamond.

In the disclosure, the boron source may be one of solid, gas and liquid boron sources. The solid and liquid boron sources should be gasified before use.

Preferably, the boron-containing gas is B₂He, and the carbon-containing gas is CH₄.

Preferably, in step H, the first-stage deposition is carried out at a gas flow rate ratio hydrogen:carbon-containing gas:boron-containing gas of 97 sccm: 3 sccm: 0.1-0.3 sccm. The second-stage deposition is carried out at a gas flow rate ratio hydrogen:carbon-containing gas:boron-containing gas of 97 sccm: 3 sccm: 0.4-0.6 sccm. The third-stage deposition is carried out at a gas flow rate ratio hydrogen:carbon-containing gas:boron-containing gas of 97 sccm: 3 sccm: 0.8-1.5 sccm.

According to the method for preparing a high-specific surface area and super-hydrophilic gradient boron-doped diamond electrode of the disclosure, in step II, the first-stage deposition is carried out at a temperature of 600-1000° C. under a pressure of 10³-10⁴ Pa for 1-3 h. The second-stage deposition is carried out at a temperature of 600-1000° C. under a pressure of 10³-10⁴ Pa for 3-48 h. The third-stage deposition is carried out at a temperature of 600-1000° C. under a pressure of 10³-10⁴ Pa for 1-12 h.

According to the high-specific surface area and super-hydrophilic gradient boron-doped diamond electrode of the disclosure, in step III, the heat treatment is carried out at a temperature of 500-800° C. for 15-40 min.

In the disclosure, through the high-content boron doping in the top layer and the heat treatment, the boron-doped diamond layer has an oxygen evolution potential of greater than 2.3 V and a potential window of greater than 3.0 V, such that the surface of the electrode has improved electrocatalytic oxidation performance and excellent hydrophilicity (the contact angle is θ<40°). The inventors found that the electrocatalytic oxidation performance (i.e. electrochemical activity) of the electrode can be changed by adjusting the doping content of boron in the top layer of the material. With the increase of the boron content, the electrocatalytic oxidation performance of the electrode is improved, but the sp² phase on the surface will also increase. The increase of the sp² phase will lead to the decrease of the oxygen evolution potential and the decrease of the potential window. The sp² phase in the material can be etched off by high-temperature oxidation. Thus, the material can have a low sp² content (exhibiting a high oxygen evolution potential of greater than 2.3 V and a potential window of greater than 3.0 V) and a higher boron content (good electrocatalytic oxidation performance). Meanwhile, on the surface of the boron-doped diamond, high-temperature heat treatment is carried out in oxygen or air so as to remove the graphite phase on the surface and also etch the diamond. At high temperature, the graphite phase on the surface of the diamond will lose weight first, and as the temperature changes, the diamond will lose weight. Finally, a large number of micropores and spikes are formed on the surface of the diamond, which increases the specific surface area and greatly improves the hydrophilicity.

According to the application of a high-specific surface area and super-hydrophilic gradient boron-doped diamond electrode of the disclosure, the gradient boron-doped diamond electrode is applied to treatment of wastewater, sterilization and organic pollutant removal of various types of daily water, water purifiers or electrochemical biosensors.

According to the application of a high-specific surface area and super-hydrophilic gradient boron-doped diamond electrode of the disclosure, the boron-doped diamond electrode is applied to electrochemical biosensors, electrochemical synthesis or electrochemical detection.

Beneficial effects are as follows:

According to the gradient boron-doped diamond layer provided by the disclosure, the doping content of boron in the prepared BDD electrode material gradually increases from the bottom to the top of the thin film. The doping content of boron in the bottom layer with high adhesion is extremely low so as to ensure the bonding and stability of the thin film. The bottom layer is in direct contact with the electrode matrix. In the early stage of deposition, the diamond phase is easy to nucleate, with fewer defects and less sp² carbon. This can further increase the sp³ content and lattice stability of the nucleation surface, thereby increasing the adhesion to the electrode matrix. The middle layer, which is corrosion-resistant, has a medium boron content (i.e. higher than the bottom layer and lower than the top layer). The boron content in the middle layer is still very low, which can thus ensure the purity of the sp² phase (i.e., the diamond is dense and continuous). In addition, the certain doping content of boron can also ensure the conductivity of this layer. The high doping content of boron in the top layer can improve the conductivity and electrochemical activity of the material, so that the top layer has wide potential window, high oxygen evolution potential and low background current. The diamond top layer can greatly improve the electrocatalytic activity and degradation efficiency of the electrode. Meanwhile, the hydrophilicity will also increase with the increase of the boron content. Compared with the traditional BDD electrode material, the BDD electrode material of the disclosure has longer service life, higher catalytic activity and lower application cost, and is more in line with the requirements of the actual application environment.

In the preparation method of the disclosure, by combining the high-content boron doping in the top layer and one-step high-temperature oxidation etching, the surface with both excellent catalytic activity and excellent hydrophilicity is obtained. The one-step high-temperature oxidation etching in the disclosure is simple in process, does not introduce additional metal ions, and can effectively remove sp² carbon (graphite) and other impurities on the surface of the material, thereby further improving the performance of the BDD material. Moreover, irregular spikes/micropores are formed on the surface of the material by etching. The introduction of such micro/nano structures will effectively increase the specific surface area of the electrode and improve the flow state (i.e., the turbulence intensity) of the water body on the surface of the electrode. The combined effect will significantly improve the mineralization efficiency of the electrode material for organic matters. In the treatment process, the surface morphology will affect the hydrophilicity of the surface of the material. Surface hydrophilicity is one of significant surface properties of an object. A contact angle of a liquid on the surface of a solid material, i.e., an included angle θ formed between a tangent to the gas-liquid interface through the intersection of gas, liquid and solid in the liquid side and the solid-liquid boundary, is a measure of wettability. If θ is less than 90°, then the solid surface is hydrophilic, i.e., the liquid can easily wet the solid. A smaller contact angle indicates a better wettability. If θ is greater than 90°, then the solid surface is hydrophobic, i.e., the liquid does not wet the solid easily and moves easily on the surface. In the disclosure, the BDD electrode material subjected to high-temperature treatment exhibits improved surface hydrophilicity, and even tends to be superhydrophilic (the contact angle is θ<20°). This is because the high-temperature oxidation treatment can not only remove sp² on the surface, which improves the quality of the diamond, but also selectively etch and remove part of diamond and non-diamond phases with specific crystal faces in the diamond film. After being subjected to the heat treatment, the electrode is mainly composed of the sp3 phase with higher surface tension, and the surface structure changes significantly. Compared with the unetched electrode, the rough surface morphology with spikes and micropores play a key role in supporting the droplets, causing the establishment of the Cassie state. Therefore, the hydrophilicity is greatly improved.

Based on the above, according to the high-specific surface area and super-hydrophilic gradient boron-doped diamond electrode and the method for preparing same in the disclosure, the high-temperature oxidation etching which is simple in process and does not introduce contaminants is used to treat the BDD, which improves the mineralization and degradation efficiency of the BDD electrode and also provide superhydrophilicity to the BDD electrode. Compared with similar processes, this process is simple to operate, low in cost and good in performance, and thus, is more suitable for large-scale industrialized application.

### BRIEF DESCRIPTION OF THE DRAWINGS

FIG. 1 shows SEM images of a BDD electrode material prepared in Embodiment 1 before and after high-temperature treatment. The left image is the SEM image of the BDD electrode material before the high-temperature treatment, and the right image is the SEM image of the finished BDD electrode material after the high-temperature treatment.

FIG. 2 shows images showing hydrophilicity of the BDD electrode material prepared in Embodiment 1 before and after the high-temperature treatment. The left image shows the room-temperature contact angle of the BDD electrode material before the high-temperature treatment, and the right image shows the room-temperature contact angle of the BDD electrode material after the high-temperature treatment.

FIGS. 3A-3B show degradation efficiency curves of reactive blue 19 by the BDD electrode material prepared in Embodiment 1 before and after the high-temperature treatment: FIG. 3A shows a color remove versus time curve; and FIG. 3B shows a COD (chemical oxygen demand) remove versus time curve.

FIG. 4 shows SEM images of a BDD electrode material prepared in Embodiment 2 before and after high-temperature treatment. The left image is the SEM image of the BDD electrode material before the high-temperature treatment, and the right image is the SEM image of the finished BDD electrode material after the high-temperature treatment.

FIG. 5 shows images showing Raman spectra of the BDD electrode material prepared in Embodiment 2 before and after the high-temperature treatment. The lower curve is the Raman spectrum of the BDD electrode material before the high-temperature treatment, and the upper curve is the Raman spectrum of the finished BDD electrode material after the high-temperature treatment.

FIG. 6 shows images showing hydrophilicity of the BDD electrode material prepared in Embodiment 2 before and after the high-temperature treatment. The left image shows the room-temperature contact angle of the BDD electrode material before the high-temperature treatment, and the right image shows the room-temperature contact angle of the BDD electrode material after the high-temperature treatment.

FIG. 7 shows SEM images of a BDD electrode material prepared in Embodiment 3 before and after high-temperature treatment. The left image is the SEM image of the BDD electrode material before the high-temperature treatment, and the right image is the SEM image of the finished BDD electrode material after the high-temperature treatment.

FIG. 8 shows images of surface morphology of the finished BDD electrode material prepared in Embodiment 3 before and after 300 hours of accelerated life testing. The left image shows the morphology of the material before the 300 hours of accelerated life testing, and the right image shows the morphology of the material after the 300 hours of accelerated life testing.

FIG. 9 shows degradation efficiency curves of organic wastewater by the BDD electrode material prepared in Embodiment 3 before and after the high-temperature treatment.

FIG. 10 shows a structure of a water purifier in Embodiment 3: 1, housing; 2, separator; 3, metal electrode; 4, BDD electrode; 5, conductive clip; 6, sealed insulator; and 7, wire.

FIG. 11 shows a room-temperature contact angle of the finished BDD electrode material prepared in Comparative Embodiment 1.

FIG. 12 shows an SEM image of the finished BDD electrode material prepared in Comparative Embodiment 3.

### DETAILED DESCRIPTION OF THE EMBODIMENTS

### Embodiment 1

BDD Electrode Material with Ti Substrate.

This BDD electrode used titanium (Ti) as the substrate for BDD deposition. This is because it is easy to form a carbide transition layer on the surface of Ti, and Ti has a thermal expansion coefficient matched with that of C, so it is easy to form a BDD thin film with good bonding. Both Ti and C have good corrosion resistance and stability. The preparation process is as follows.

2. Preparation of BDD Material.

2.1 Pretreatment of Substrate Material.

First, Ti was cut into a plate-like sample with a size of 30×20×2 mm, which was polished with 600-grit, 800-grit and 1000-grit metallographic abrasive papers. The polished Ti substrate was immersed in acetone (CH₃COCH₃) and anhydrous ethanol (C₂H₅OH) and subjected to ultrasonic oscillation for 10 min. Then, the Ti substrate was placed in a nano-diamond suspension, and seed crystals were grown for 30 min under the action of ultrasound to enhance the nucleation. Finally, the Ti substrate was rinsed with deionized ultrapure water and dried for later use.

2.2 Deposition of BDD Thin Film.

The hot filament used in this example was φ0.5 mm straight tungsten wire, which completely covered the substrate. The pretreated substrate was placed into a chamber of HFCVD equipment, and the distance between the hot filament and the substrate was adjusted (to 10 mm). After the completion of the installation, the door was closed, and the chamber was vacuumized. Then, hydrogen, methane and borane (diborane used in this experiment was a gas mixture of B₂H₆ and H₂ in a ratio of 5:95) were introduced according to a set concentration ratio of gas sources of the experiment. After the reactive gas sources were uniformly mixed, a suction valve was closed, and a micrometering valve was adjusted to adjust the pressure in the chamber to a set pressure. Then, the HFCVD equipment was powered on, the current was adjusted such that the hot filament was heated to a preset temperature, and at the same time, the pressure in the deposition chamber was observed. If the pressure changed, the micrometering valve was used to adjust the pressure. Then, the deposition of the boron-doped diamond thin film was started. After the completion of the deposition, the temperature of the deposition chamber was reduced by adjusting the magnitude of the current. At this time, CH₄ and B₂H₆ needed to be stopped, only H₂ was used to etch the graphite phase on the surface of the diamond. In this example, the BDD electrode material was subjected to a three-stage deposition process. The first-stage deposition was carried out at a gas flow rate ratio H₂:B₂H₆:CH₄ of 97 sccm:0.1 sccm:3.0 sccm under a pressure of 2 kPa at a temperature of 850° C. for 4 h. The second-stage deposition was carried out at a gas flow rate ratio H₂:B₂H₆:CH₄ of 97 sccm:0.4 sccm:3.0 sccm under a pressure of 2 kPa at a temperature of 850° C. for 8 h. The third-stage deposition was carried out at a gas flow rate ratio H₂:B₂H₆:CH₄ of 97 sccm:1.0 sccm:3.0 sccm under a pressure of 2 kPa at a temperature of 850° C. for 12 h.

2.3 High-Temperature Oxidation Treatment of BDD Thin Film.

After the completion of the deposition, the obtained BDD electrode material was placed in a crucible. A heating program of a tube furnace was set: in an air atmosphere, the temperature was raised at a rate of 10° C./min to 800° C., and then held for 35 minutes. The crucible containing the BDD material was pushed into a resistance heating area. After 30 times of treatment, the crucible was pushed out of the tube furnace, and cooled at room temperature, thereby obtaining the finished BDD electrode.

2. Performance Testing.

1) The BDD electrode not subjected to high-temperature treatment and the finished BDD electrode subjected to high-temperature treatment were respectively tested for their microstructure (by a field emission electron scanning microscope). As can be seen from FIG. 1, after the high-temperature treatment, morphology distributed with irregular micropores and spikes was formed on the surface of the thin film by etching. These irregular micropores and spikes could greatly increase the specific surface area of the material.

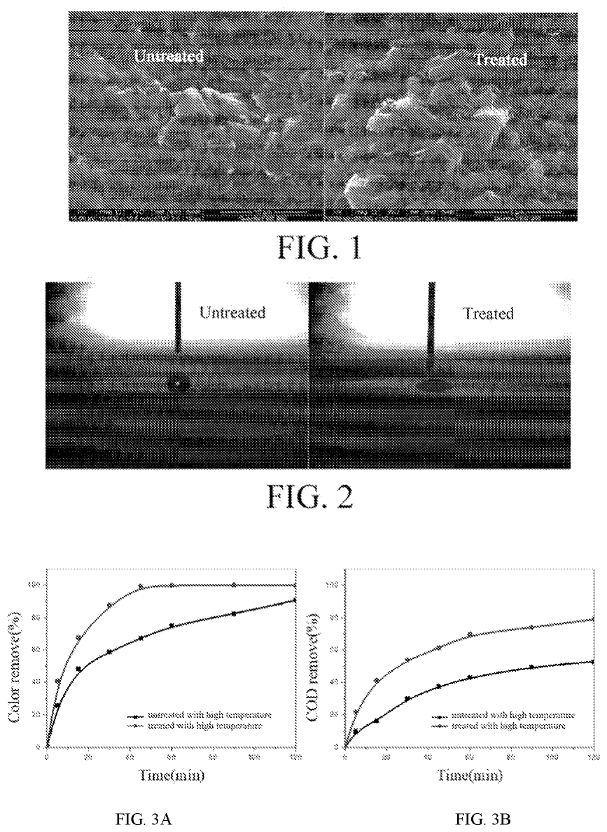

2) The BDD electrode not subjected to high-temperature treatment and the finished BDD electrode subjected to high-temperature treatment were respectively tested for their room-temperature contact angle. As shown in FIG. 2, the contact angle of the BDD electrode not subjected to high-temperature treatment was 83.2°, and the contact angle of the finished BDD electrode subjected to high-temperature treatment was 33.4°.

The contact angle is of great significance to the application of a diamond electrode material. On the one hand, the improved hydrophilicity can improve the degradation efficiency in the degradation process. On the other hand, when the material is used in the field of electrochemical analysis, the surface hydrophilicity of the electrode material will affect the molecular weight to be detected adsorbed by the electrode material, which will restrict the degree of electrochemical catalytic reaction and further control the strength of the electrochemical signal.

3) Encapsulation of BDD electrode: The surface of the matrix on which BDD had not been deposited was first polished with abrasive paper, in order to remove oil stains and impurities on the matrix. Then, a copper wire was spread on the surface of the Ti substrate, and bonded to the back surface of the BDD sample with a silver conductive adhesive to avoid the copper wire from being exposed. The silver conductive adhesive was allowed to stand for about 2 h until it was completely solidified. Finally, epoxy resin AB glue was uniformly applied to the surface of the BDD electrode except where the diamond was deposited. After about 6 hours, the strength of the insulating glue would reach its maximum. The encapsulation effect was tested with a multimeter.

4) The encapsulated electrodes (including the finished BDD electrode subjected to high-temperature oxidation treatment and the electrode not subjected to high-temperature oxidation treatment in Embodiment 1) were used to degrade reactive blue. The results are shown in FIGS. 3A-3B. FIG. 3A shows color remove in the water sample in the degradation process: the color remove of the treated electrode material was 100%, and the color remove of the untreated material was 90.2%. The color remove can reflect the degree of destruction of organic chromophores. As can be seen, the electrode material subjected to high-temperature oxidation treatment had a larger specific surface area in the degradation process, and thus, could produce more active substances (such as hydroxyl radicals, active chlorine, etc.) on its surface, which thereby further oxidized the organic pollutants in the water body. FIG. 3B shows the change of COD (chemical oxygen demand) in the water body as a function of time in the degradation process. After 120 min of degradation, the COD remove of the electrode material subjected to high-temperature treatment could reach 79.5%, and the COD remove of the untreated electrode was only 50.1%. COD could further reflect the organic content in the water body, and thus was used as the evaluation indicator. Both the color remove and the COD remove showed that the treated electrode material had a significantly improved degradation efficiency.

### Embodiment 2

Preparation of BDD Material with Nickel Substrate.

Nickel (Ni), as a common electrocatalytic material that can be easily electrodeposited, can be processed into complex structures and shapes. Therefore, a BDD thin film was prepared on a Ni substrate in this example.

2. Preparation of BDD Material.

2.1 Pretreatment of Substrate Material.

First, Ni was cut into a plate-like sample with a size of 25×30×2 mm. Then, the Ni substrate was immersed in acetone (CH₃COCH₃) and anhydrous ethanol (C₂H₅OH) and subjected to ultrasonic oscillation for 10 min. Finally, the Ni substrate was rinsed with deionized ultrapure water and dried for later use.

2.2 Preparation of Transition Layer.

Ni can easily catalyze the reaction of diamond to form other amorphous carbon, so it is impossible to directly deposit a boron-doped diamond film. Due to the big difference in thermal expansion coefficient between Ni and C, it impossible to form an effective carbide transition layer, and foam has poor bonding with the substrate. During the degradation experiment, Ni is easily sacrificed, resulting in a reduced service life of the BDD electrode. Therefore, in the disclosure, a Ti film that could completely cover the matrix was first sputtered on the foam Ni matrix. Ti not only could easily form a TiC layer with C, thus solving the problem of thermal mismatch, but also had good bonding with Ni.

Deposition of BDD Thin Film.

The hot filament used in this example was a φ0.5 mm straight tungsten wire, which completely covered the substrate. The pretreated substrate was placed into a chamber of HFCVD equipment, and the distance between the hot filament and the substrate was adjusted (to 8 mm). After the completion of the installation, the door was closed, and the chamber was vacuumized. Then, hydrogen, methane and borane (diborane used in this experiment was a gas mixture of B₂H₆ and H₂ in a ratio of 5:95) were introduced according to a set concentration ratio of gas sources of the experiment. After the reactive gas sources were uniformly mixed, a suction valve was closed, and a micrometering valve was adjusted to adjust the pressure in the chamber to a set pressure. Then, the HFCVD equipment was powered on, the current was adjusted such that the hot filament was heated to a preset temperature, and at the same time, the pressure in the deposition chamber was observed. If the pressure changed, the micrometering valve was used to adjust the pressure. Then, the deposition of the boron-doped diamond thin film was started. After the completion of the deposition, the temperature of the deposition chamber was reduced by adjusting the magnitude of the current. At this time, CH₄ and B₂H₆ needed to be stopped, only H₂ was used to etch the graphite phase on the surface of the diamond. In this example, the BDD electrode material was subjected to a three-stage deposition process. The first-stage deposition was carried out at a gas flow rate ratio H₂:B₂H₆:CH₄ of 97 sccm:0.1 sccm:3.0 sccm under a pressure of 3 kPa at a temperature of 850° C. for 4 h. The second-stage deposition was carried out at a gas flow rate ratio H₂:B₂H₆:CH₄ of 97 sccm:0.4 sccm:3.0 sccm under a pressure of 3 kPa at a temperature of 850° C. for 8 h. The third-stage deposition was carried out at a gas flow rate ratio H₂:B₂H₆:CH₄ of 97 sccm:1.0 sccm:3.0 sccm under a pressure of 3 kPa at a temperature of 850° C. for 2 h.

2.3 High-Temperature Oxidation Treatment of BDD Thin Film.

After the completion of the deposition, the obtained BDD electrode material was placed in a crucible. A heating program of a tube furnace was set: in an air atmosphere, the temperature was raised at a rate of 10° C./min to 500° C., and then held for 20 minutes. The crucible containing the BDD material was pushed into a resistance heating area. After 15 times of treatment, the crucible was pushed out of the tube furnace, and cooled at room temperature.

2. Performance Testing.

1) The BDD electrode not subjected to high-temperature treatment and the finished BDD electrode subjected to high-temperature treatment were respectively tested for their microstructure (by a field emission electron scanning microscope). As can be seen from FIG. 4, after the high-temperature treatment, morphology distributed with irregular micropores and spikes was formed on the surface of the thin film by etching. These irregular micropores and spikes could greatly increase the specific surface area of the material. Besides, as can be seen, after 10 min of treatment at 500° C., the graphite phase and stains on the surface of the material were effectively removed.

The existence of sp² carbon (graphitic carbon) will destroy the weak surface adsorption of the electrode material. On the one hand, this will make the electrode material easily adsorb organic matters when being used for electrochemical oxidation treatment of organic pollutants in a water body, causing reduced active area and reduced degradation and mineralization efficiency of the electrode. On the other hand, the active substance (OH) produced by the electrode during working will be adsorbed, which will lead to reduced mineralization efficiency of the active substance and thus reduced degradation efficiency. Besides, compared with the sp³ carbon (diamond phase), the sp² carbon are more easily corroded, which will reduce the oxygen evolution potential of the electrode and thereby lead to a large amount of energy consumed during actual service in favor of side reactions (i.e., oxygen evolution, etc.), causing a significant increase in useless and wasteful energy consumption. Therefore, the removal of the sp² phase is crucial to the performance of the BDD electrode material.

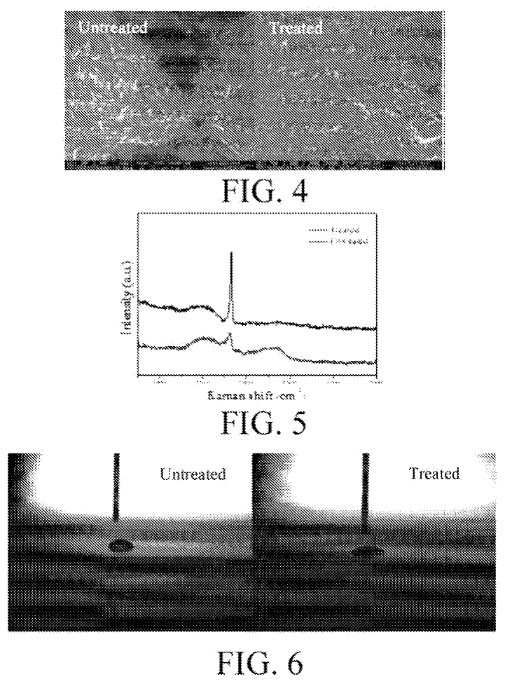

2) The BDD electrode not subjected to high-temperature treatment and the finished BDD electrode subjected to high-temperature treatment were respectively subjected to Raman spectroscopy. The results are shown in FIG. 5. The intensity at 1580 cm⁻¹ shows the sp² content in the material, and the intensity at 1332 cm⁻¹ shows the content of sp; (diamond phase) in the material. As can be seen, after 10 min of treatment at 500° C., the content of the sp² phase in the material significantly decreased, indicating an improved purity of the diamond phase, which was consistent with the analysis results obtained by SEM.

3) The BDD electrode not subjected to high-temperature treatment and the finished BDD electrode subjected to high-temperature treatment were respectively tested for their room-temperature contact angle. As shown in FIG. 6, the contact angle of the BDD electrode not subjected to high-temperature treatment was 66.5°, and the contact angle of the finished BDD electrode subjected to high-temperature treatment was 38.5°.

The contact angle is of great significance to the application of a diamond electrode material. On the one hand, the improved hydrophilicity can improve the degradation efficiency in the degradation process. On the other hand, when the material is used in the field of electrochemical analysis, the surface hydrophilicity of the electrode material will affect the molecular weight to be detected adsorbed by the electrode material, which will restrict the degree of electrochemical catalytic reaction and further control the strength of the electrochemical signal.

4) Encapsulation of BDD electrode: The surface of the matrix on which BDD had not been deposited was first polished with abrasive paper, in order to remove oil stains and impurities on the matrix. Then, a copper wire was spread on the surface of the Ti substrate, and bonded to the back surface of the BDD sample with a silver conductive adhesive to avoid the copper wire from being exposed. The silver conductive adhesive was allowed to stand for about 2 h until it was completely solidified. Finally, epoxy resin AB glue was uniformly applied to the surface of the BDD electrode except where the diamond was deposited. After about 6 hours, the strength of the insulating glue would reach its maximum. The encapsulation effect was tested with a multimeter.

### Embodiment 3

BDD Electrode Material with Silicon Substrate.

Silicon (Si), as the most common substrate material, has high lattice matching and bonding ability with the BDD thin film due to its good corrosion resistance and low thermal expansion coefficient. In this example, plate-like p-type silicon was used as the substrate material for the experiment.

2. Preparation of BDD Material.

2.1 Pretreatment of Substrate Material.

First, Si was cut into a plate-like sample with a size of 20×30×0.5 mm. Then, the Si substrate was immersed in acetone (CH₃COCH₃) and anhydrous ethanol (C₂H₅OH) and subjected to ultrasonic oscillation for 10 min. Finally, the Si substrate was rinsed with deionized ultrapure water and dried for later use.

2.2 Deposition of BDD Thin Film.

The hot filament used in this example was a φ0.5 mm straight tungsten wire, which completely covered the substrate. The pretreated substrate was placed into a chamber of HFCVD equipment, and the distance between the hot filament and the substrate was adjusted (to 10 mm). After the completion of the installation, the door was closed, and the chamber was vacuumized. Then, hydrogen, methane and borane (diborane used in this experiment was a gas mixture of B₂H₆ and H₂ in a ratio of 5:95) were introduced according to a set concentration ratio of gas sources of the experiment. After the reactive gas sources were uniformly mixed, a suction valve was closed, and a micrometering valve was adjusted to adjust the pressure in the chamber to a set pressure. Then, the HFCVD equipment was powered on, the current was adjusted such that the hot filament was heated to a preset temperature, and at the same time, the pressure in the deposition chamber was observed. If the pressure changed, the micrometering valve was used to adjust the pressure. Then, the deposition of the boron-doped diamond thin film was started. After the completion of the deposition, the temperature of the deposition chamber was reduced by adjusting the magnitude of the current. At this time, CH₄ and B₂H₆ needed to be stopped, only H₂ was used to etch the graphite phase on the surface of the diamond. In this example, the BDD electrode material was subjected to a three-stage deposition process. The first-stage deposition was carried out at a gas flow rate ratio H₂:B₂H₆:CH₄ of 97 sccm:0.1 sccm:3.0 sccm under a pressure of 3 kPa at a temperature of 850° C. for 4 h. The second-stage deposition was carried out at a gas flow rate ratio H₂:B₂H₆:CH₄ of 97 sccm:0.5 sccm:3.0 sccm under a pressure of 3 kPa at a temperature of 850° C. for 8 h. The third-stage deposition was carried out at a gas flow rate ratio H₂:B₂H₆:CH₄ of 97 sccm:1.5 sccm:3.0 sccm under a pressure of 3 kPa at a temperature of 850° C. for 1.5 h.

2.3 High-Temperature Oxidation Treatment of BDD Thin Film.

After the completion of the deposition, the obtained BDD electrode material was placed in a crucible. A heating program of a tube furnace was set: in an air atmosphere, the temperature was raised at a rate of 10° C./min to 800° C., and then held for 45 minutes. The crucible containing the BDD material was pushed into a resistance heating area. After 40 times of treatment, the crucible was pushed out of the tube furnace, and cooled at room temperature. The stability of the electrode is crucial for the service cost of the material, and is also a key link in the industrial chain of the material. In this example, by controlling the treatment temperature and time, the BDD electrode material was etched into porous morphology, and then tested for its stability.

2. Performance Testing.

1) The BDD electrode not subjected to high-temperature treatment and the finished BDD electrode subjected to high-temperature treatment were respectively tested for their microstructure (by a field emission electron scanning microscope). As can be seen from FIG. 7, after the high-temperature treatment, morphology distributed with irregular micropores and spikes was formed on the surface of the thin film by etching.

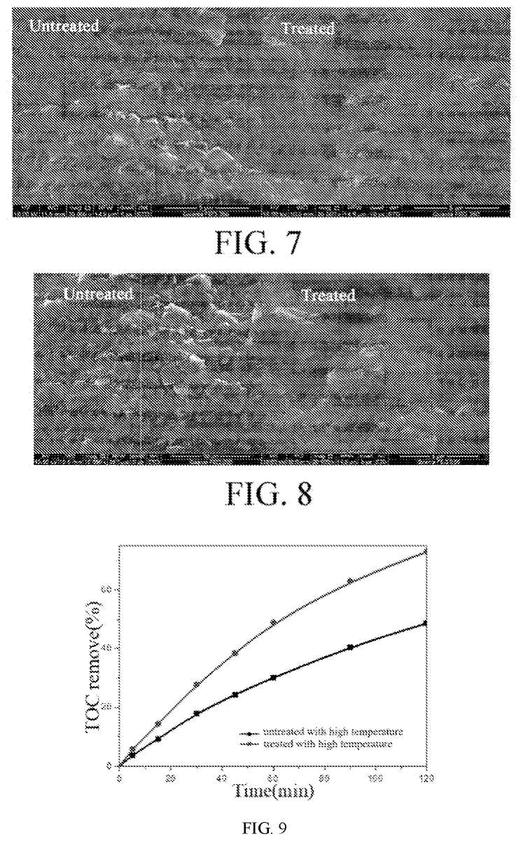

2) The finished BDD electrode was tested for its stability using accelerated life testing. After the finished BDD electrode was run in a 1 mol/L sulfuric acid solution at a current density of 1 A/cm2 for 300 hours, the surface topography was characterized. As shown in FIG. 8, there was no significant thin film falling off the electrode, and the surface topography was still stable.

3) Encapsulation of BDD electrode: The surface of the matrix on which BDD had not been deposited was first polished with abrasive paper, in order to remove oil stains and impurities on the matrix. Then, a copper wire was spread on the surface of the Ti substrate, and bonded to the back surface of the BDD sample with a silver conductive adhesive to avoid the copper wire from being exposed. The silver conductive adhesive was allowed to stand for about 2 h until it was completely solidified. Finally, epoxy resin AB glue was uniformly applied to the surface of the BDD electrode except where the diamond was deposited. After about 6 hours, the strength of the insulating glue would reach its maximum. The encapsulation effect was tested with a multimeter.

4) The encapsulated electrodes (including the finished BDD electrode subjected to high-temperature oxidation treatment and the electrode not subjected to high-temperature oxidation treatment in Embodiment 3) were used to degrade organic wastewater. Actual wastewater has a more complex composition and provides a more hostile experimental environment (pH, etc.). As a result, in this example, the electrode materials (subjected to high-temperature oxidation treatment and not subjected to high-temperature oxidation treatment) were used to degrade actual wastewater (pharmaceutical wastewater from a factory in Gansu Province), so as to verify the promotion effect of high-temperature oxidation on degradation efficiency after increasing the specific surface area and sp² purity of the electrode. Due to the complex composition of the actual wastewater as well as complex types and contents of organic pollutants and salts, TOC (total organic carbon) was used as the evaluation indicator. TOC remove can reflect the degree to which organic pollutants in the water body are mineralized to water and carbon dioxide. It can be clearly seen from FIG. 9 that after the wastewater was degraded with the electrode material subjected to high-temperature oxidation treatment, the degree of mineralization of the organic matters in the water body was significantly increased. After 120 min of degradation, the TOC remove of the electrode material subjected to high-temperature oxidation treatment could reach 73.4%, and the TOC remove of the untreated electrode material was only 47.3%, indicating that the treated electrode material had a significantly improved degradation efficiency.

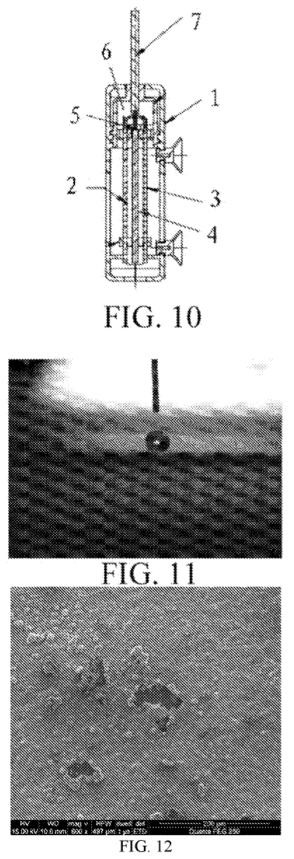

5) The BDD electrode prepared in Embodiment 3 was applied to a water purifier. The water purifier, as shown in FIG. 10, included a housing 1, a separator 2, a metal electrode 3, a BDD electrode 4, a conductive clip 5, a sealed insulator 6 and a wire 7.

In actual application, an electrode assembly formed by the BDD electrode prepared in Embodiment 3 as an anode, a titanium electrode as a cathode, and a perfluorinated ion-exchange membrane as a separator was installed in a water purifier (FIG. 10), and the water purifier was placed in a water sample to be treated (in a fishbowl containing live fish) and run under a voltage of 3 V for 5 h. The COD in the water sample to be treated was reduced from 983 mg/L to 50 mg/L.

### Comparative Embodiment 1

The conditions were the same as in Embodiment 2, except that gradient doping was not used in the deposition of the thin film. The deposition was carried out at a gas flow rate ratio H₂:B₂H₆:CH₄ of 97 sccm:0.4 sccm:3.0 sccm under a pressure of 3 kPa at a temperature of 850° C. for 14 h. The material was tested for its surface hydrophilicity. As shown in FIG. 11, the room-temperature contact angle of the material was 82.4°.

### Comparative Embodiment 2

The conditions were the same as those in Embodiment 2, except that the deposition of the top layer of the material was carried out at a gas flow rate ratio H₂:B₂H₆:CH₄ of 97 sccm:1.0 sccm:3.0 sccm. The room-temperature water contact angle of the gradient boron-doped sample was 66.7°, indicating a significant decrease of the hydrophilicity.

### Comparative Embodiment 3

The conditions were the same as in Embodiment 3, except that the high-temperature treatment was carried out for 120 min. The surface topography of the electrode material obtained after high-temperature treatment is shown in FIG. 12. Due to the excessive treatment time, the thin film was damaged seriously (over a large area), and the substrate material was exposed. At this time, the material was no longer able to perform normally, exhibiting a significant decrease in both performance and service life.

What is claimed is:

1. A high-specific surface area and super-hydrophilic gradient boron-doped diamond electrode, wherein in the high-specific surface area and super-hydrophilic gradient boron-doped diamond electrode, a substrate is directly used as an electrode matrix; or a transition layer is disposed on a surface of the substrate and used as the electrode matrix, and a gradient boron-doped diamond layer is disposed on a surface of the electrode matrix, and wherein a contact angle θ of the high-specific surface area and super-hydrophilic gradient boron-doped diamond electrode is less than 40°.

2. The high-specific surface area and super-hydrophilic gradient boron-doped diamond electrode according to claim 1, wherein the gradient boron-doped diamond layer comprises, in a succession from a bottom to a top, a gradient boron-doped diamond bottom layer, a gradient boron-doped diamond middle layer, and a gradient boron-doped diamond top layer, and boron contents of the gradient boron-doped diamond bottom layer, the gradient boron-doped diamond middle layer, and the gradient boron-doped diamond top layer gradually increase; wherein in the gradient boron-doped diamond bottom layer, an atomic ratio B/C is 3333 ppm-33333 ppm; in the gradient boron-doped diamond middle layer, an atomic ratio B/C is 10000 ppm-33333 ppm; and in the gradient boron-doped diamond top layer, an atomic ratio B/C is 16666 ppm-50000 ppm.

3. The high-specific surface area and super-hydrophilic gradient boron-doped diamond electrode according to claim 2, wherein the gradient boron-doped diamond layer is uniformly deposited on the surface of the substrate by a chemical vapor deposition, the gradient boron-doped diamond layer has a thickness of 5 μm-2 mm; and a thickness of the gradient boron-doped diamond middle layer accounts for 50/6-90% of the thickness of the gradient boron-doped diamond layer.

4. The high-specific surface area and super-hydrophilic gradient boron-doped diamond electrode according to claim 1, wherein a substrate material is selected from one of metals nickel, niobium, tantalum, copper, titanium, cobalt, tungsten, molybdenum, chromium, and iron or one of an alloy of the nickel, an alloy of niobium, an alloy of tantalum, an alloy of copper, an alloy of titanium, an alloy of cobalt, an alloy of tungsten, an alloy of molybdenum, an alloy of chromium, and an alloy of iron; or an electrode substrate material is selected from one of ceramics Al₂O₃, ZrO₂, SiC, Si₃N₄, BN, B₄C, AlN, TiB₂, TiN, WC, Cr₇C₃, Ti₂GeC, Ti₂AlC and Ti₂AlN, Ti₃SiC₂, Ti₃GeC₂, Ti₃AlC₂, Ti₄AlC₃, and BaPO₃, or a doped ceramic of the Al₂O₃, a doped ceramic of the ZrO₂, a doped ceramic of the SiC, a doped ceramic of the Si₃N₄, a doped ceramic of the BN, a doped ceramic of the B₄C, a doped ceramic of the AlN, a doped ceramic of the TiB₂, a doped ceramic of the TiN, a doped ceramic of the WC, a doped ceramic of the Cr₇C₃, a doped ceramic of the Ti₂GeC, a doped ceramic of the Ti₂AlC and the Ti₂AlN, a doped ceramic of the Ti₃SiC₂, a doped ceramic of the Ti₃GeC₂, a doped ceramic of the Ti₃AlC₂, a doped ceramic of the Ti₄AlC₃, and a doped ceramic of the BaPO₃; or the substrate material is selected from one of composite materials comprising the metals and the ceramics, or the substrate material is selected from a diamond or Si;
the substrate is in a shape of a solid cylinder, a hollow cylinder, or a plate; and
the substrate is in a three-dimensional continuous network structure, a two-dimensional continuous network structures, or a two-dimensional closed plate structure.

5. The high-specific surface area and super-hydrophilic gradient boron-doped diamond electrode according to claim 1, wherein a transition layer material is selected from at least one of titanium, tungsten, molybdenum, chromium, tantalum, platinum, silver, aluminum, copper, and silicon, and the transition layer has a thickness of 50 nm-10 μm.

6. The high-specific surface area and super-hydrophilic gradient boron-doped diamond electrode according to claim 1, wherein micropores and/or spikes are distributed on a surface of the gradient boron-doped diamond layer, and wherein the micropores have a diameter of 500 nm-0.5 mm, and the spikes have a diameter of 1 μm-30 μm.

7. A method for preparing the high-specific surface area and super-hydrophilic gradient boron-doped diamond electrode according to claim 1, comprising the following steps:
step I: pretreating the electrode matrix
putting the electrode matrix into a suspension containing nanocrystalline and/or microcrystalline diamond mixed particles; carrying out an ultrasonic treatment and drying; obtaining the electrode matrix with nanocrystalline and/or microcrystalline diamonds adsorbed to the surface of the electrode matrix;
step II: depositing the gradient boron-doped diamond layer
putting the electrode matrix obtained in the step I into a chemical vapor deposition reactor, and carrying out a three-stage deposition on the surface of the electrode matrix to obtain the gradient boron-doped diamond layer, wherein in a first-stage deposition process, a carbon-containing gas accounts for 1%-5% of a mass flow rate of all gasses in the chemical vapor deposition reactor, and a boron-containing gas accounts for 0.005%-0.05% of the mass flow rate of all the gasses in the chemical vapor deposition reactor; in a second-stage deposition process, the carbon-containing gas accounts for 1%-5% of the mass flow rate of all the gasses in the chemical vapor deposition reactor, and the boron-containing gas accounts for 0.015%-0.05% of the mass flow rate of all the gasses in the chemical vapor deposition reactor; and in a third-stage deposition process, the carbon-containing gas accounts for 1%-5% of the mass flow rate of all the gasses in the chemical vapor deposition reactor, and the boron-containing gas accounts for 0.025%-0.075% of the mass flow rate of all the gasses in the chemical vapor deposition reactor; and
step III: performing a high-temperature treatment
carrying out a heat treatment on the electrode matrix with the gradient boron-doped diamond layer at a temperature of 400° C.-1200° C. for 5 min-110 min, wherein the heat treatment is carried out under a pressure of 10 Pa-10⁵ Pa in an etching atmosphere.

8. The method for preparing the high-specific surface area and super-hydrophilic gradient boron-doped diamond electrode according to claim 7, wherein in the step II, the first-stage deposition process is carried out at a temperature of 600° C.-1000° C. under a pressure of 10³ Pa-10⁴ Pa for 1 h-3 h; the second-stage deposition process is carried out at a temperature of 600° C.-1000° C. under a pressure of 10³ Pa-10⁴ Pa for 3 h-48 h; and the third-stage deposition process is carried out at a temperature of 600° C.-1000° C. under a pressure of 10³ Pa-10⁴ Pa for 1 h-12 h.

9. The method for preparing the high-specific surface area and super-hydrophilic gradient boron-doped diamond electrode according to claim 7, wherein in the step III, the heat treatment is carried out at the temperature of 500° C.-800° C. for 15 min-40 min.

10. A method of an application of the high-specific surface area and super-hydrophilic gradient boron-doped diamond electrode according to claim 1, wherein the high-specific surface area and super-hydrophilic gradient boron-doped diamond electrode is applied to an electrochemical oxidation treatment of a wastewater, a sterilization, and an organic pollutant removal of various types of a daily water, water purifiers, or electrochemical biosensors.

11. The method for preparing the high-specific surface area and super-hydrophilic gradient boron-doped diamond electrode according to claim 7, wherein the gradient boron-doped diamond layer comprises, in a succession from a bottom to a top, a gradient boron-doped diamond bottom layer, a gradient boron-doped diamond middle layer, and a gradient boron-doped diamond top layer, and boron contents of the gradient boron-doped diamond bottom layer, the gradient boron-doped diamond middle layer, and the gradient boron-doped diamond top layer gradually increase; wherein in the gradient boron-doped diamond bottom layer, an atomic ratio B/C is 3333 ppm-33333 ppm; in the gradient boron-doped diamond middle layer, an atomic ratio B/C is 10000 ppm-33333 ppm; and in the gradient boron-doped diamond top layer, an atomic ratio B/C is 16666 ppm-50000 ppm.

12. The method for preparing the high-specific surface area and super-hydrophilic gradient boron-doped diamond electrode according to claim 11, wherein the gradient boron-doped diamond layer is uniformly deposited on the surface of the substrate by a chemical vapor deposition, the gradient boron-doped diamond layer has a thickness of 5 μm-2 mm; and a thickness of the gradient boron-doped diamond middle layer accounts for 50%-90% of the thickness of the gradient boron-doped diamond layer.

13. The method for preparing the high-specific surface area and super-hydrophilic gradient boron-doped diamond electrode according to claim 7, wherein a substrate material is selected from one of metals nickel, niobium, tantalum, copper, titanium, cobalt, tungsten, molybdenum, chromium, and iron or one of an alloy of the nickel, an alloy of niobium, an alloy of tantalum, an alloy of copper, an alloy of titanium, an alloy of cobalt, an alloy of tungsten, an alloy of molybdenum, an alloy of chromium, and an alloy of iron; or an electrode substrate material is selected from one of ceramics Al₂O₃, ZrO₂, SiC, Si₃N₄, BN, B₄C, AlN, TiB₂, TiN, WC, Cr₇C₃, Ti₂GeC, Ti₂AlC and Ti₂AlN, Ti₃SiC₂, Ti₃GeC₂, Ti₃AlC₂, Ti₄AlC₃, and BaPO₃, or a doped ceramic of the Al₂O₃, a doped ceramic of the ZrO₂, a doped ceramic of the SiC, a doped ceramic of the Si₃N₄, a doped ceramic of the BN, a doped ceramic of the B₄C, a doped ceramic of the AlN, a doped ceramic of the TiB₂, a doped ceramic of the TiN, a doped ceramic of the WC, a doped ceramic of the Cr₇C₃, a doped ceramic of the Ti₂GeC, a doped ceramic of the Ti₂AlC and the Ti₂AlN, a doped ceramic of the Ti₃SiC₂, a doped ceramic of the Ti₆GeC₂, a doped ceramic of the Ti₃AlC₂, a doped ceramic of the Ti₄AlC₃, and a doped ceramic of the BaPO₃; or the substrate material is selected from one of composite materials comprising the metals and the ceramics, or the substrate material is selected from a diamond or Si;
the substrate is in a shape of a solid cylinder, a hollow cylinder, or a plate; and
the substrate is in a three-dimensional continuous network structure, a two-dimensional continuous network structure, or a two-dimensional closed plate structure.

14. The method for preparing the high-specific surface area and super-hydrophilic gradient boron-doped diamond electrode according to claim 7, wherein a transition layer material is selected from at least one of titanium, tungsten, molybdenum, chromium, tantalum, platinum, silver, aluminum, copper, and silicon, and the transition layer has a thickness of 50 nm-10 μm.

15. The method for preparing the high-specific surface area and super-hydrophilic gradient boron-doped diamond electrode according to claim 7, wherein micropores and/or spikes are distributed on a surface of the gradient boron-doped diamond layer, and wherein the micropores have a diameter of 500 nm-0.5 mm, and the spikes have a diameter of 1 μm-30 μm.

16. The method of the application of the high-specific surface area and super-hydrophilic gradient boron-doped diamond electrode according to claim 10, wherein the gradient boron-doped diamond layer comprises, in a succession from a bottom to a top, a gradient boron-doped diamond bottom layer, a gradient boron-doped diamond middle layer, and a gradient boron-doped diamond top layer, and boron contents of the gradient boron-doped diamond bottom layer, the gradient boron-doped diamond middle layer, and the gradient boron-doped diamond top layer gradually increase; wherein in the gradient boron-doped diamond bottom layer, an atomic ratio B/C is 3333 ppm-33333 ppm; in the gradient boron-doped diamond middle layer, an atomic ratio B/C is 10000 ppm-33333 ppm; and in the gradient boron-doped diamond top layer, an atomic ratio B/C is 16666 ppm-50000 ppm.

17. The method of the application of the high-specific surface area and super-hydrophilic gradient boron-doped diamond electrode according to claim 16, wherein the gradient boron-doped diamond layer is uniformly deposited on the surface of the substrate by a chemical vapor deposition, the gradient boron-doped diamond layer has a thickness of 5 μm-2 mm; and a thickness of the gradient boron-doped diamond middle layer accounts for 50/0-90% of the thickness of the gradient boron-doped diamond layer.

18. The method of the application of the high-specific surface area and super-hydrophilic gradient boron-doped diamond electrode according to claim 10, wherein a substrate material is selected from one of metals nickel, niobium, tantalum, copper, titanium, cobalt, tungsten, molybdenum, chromium, and iron or one of an alloy of the nickel, an alloy of niobium, an alloy of tantalum, an alloy of copper, an alloy of titanium, an alloy of cobalt, an alloy of tungsten, an alloy of molybdenum, an alloy of chromium, and an alloy of iron; or an electrode substrate material is selected from one of ceramics Al₂O₃, ZrO₂, SiC, Si₃N₄, BN, B₄C, AlN, TiB₂, TiN, WC, Cr₇C₃, Ti₂GeC, Ti₂AlC and Ti₂AlN, Ti₃SiC₂, Ti₃GeC₂, Ti₃AlC₂, Ti₄AlC₃, and BaPO₃, or a doped ceramic of the Al₂O₃, a doped ceramic of the ZrO₂, a doped ceramic of the SiC, a doped ceramic of the Si₃N₄, a doped ceramic of the BN, a doped ceramic of the B₄C, a doped ceramic of the AlN, a doped ceramic of the TiB₂, a doped ceramic of the TiN, a doped ceramic of the WC, a doped ceramic of the Cr₇C₃, a doped ceramic of the Ti₂GeC, a doped ceramic of the Ti₂AlC and the Ti₂AlN, a doped ceramic of the Ti₃SiC₂, a doped ceramic of the Ti₃GeC₂, a doped ceramic of the Ti₃AlC₂, a doped ceramic of the Ti₄AlC₃, and a doped ceramic of the BaPO₃; or the substrate material is selected from one of composite materials comprising the metals and the ceramics, or the substrate material is selected from a diamond or Si;
the substrate is in a shape of a solid cylinder, a hollow cylinder, or a plate; and
the substrate is in a three-dimensional continuous network structure, a two-dimensional continuous network structure, or a two-dimensional closed plate structure.

19. The method of the application of the high-specific surface area and super-hydrophilic gradient boron-doped diamond electrode according to claim 10, wherein a transition layer material is selected from at least one of titanium, tungsten, molybdenum, chromium, tantalum, platinum, silver, aluminum, copper, and silicon, and the transition layer has a thickness of 50 nm-10 μm.

20. The method of the application of the high-specific surface area and super-hydrophilic gradient boron-doped diamond electrode according to claim 10, wherein micropores and/or spikes are distributed on a surface of the gradient boron-doped diamond layer, and wherein the micropores have a diameter of 500 nm-0.5 mm, and the spikes have a diameter of 1 μm-30 μm.
